(19) United States
(12) Patent Application Publication
(10) Pub. No.: US 2025/0132730 A1
(43) Pub. Date: Apr. 24, 2025

(54) SPLIT POWER SUPPLY AMPLIFIER FOR OUTPUT LEAKAGE CURRENT MANAGEMENT

(71) Applicant: CIRRUS LOGIC INTERNATIONAL SEMICONDUCTOR LTD., Edinburgh (GB)

(72) Inventors: Payel Mukherjee, Edinburgh (GB); Rupesh Khare, Newbury (GB); Ambreesh Bhattad, Fountain Hills, AZ (US)

(21) Appl. No.: 18/491,252

(22) Filed: Oct. 20, 2023

(51) Int. Cl. H03F 1/02; H03F 3/213

(52) U.S. Cl. CPC H03F 1/0233; H03F 3/213; H03F 2200/462

(57) ABSTRACT

An amplifier circuit and its method of operation reduce leakage in the output stage of the under no-load or low-load conditions. The amplifier circuit includes an amplifier stage that generates an output signal, an output stage including an output device, a pre-driver device coupled to a gate of the output device, and a feedback connection from the output device to the amplifier stage. A power supply rail of the amplifier is provided by a first power supply voltage, and the output signal of the amplifier stage is coupled to an input of the pre-driver device. A power supply rail of the output stage is provided by a second power supply voltage having a magnitude less than the first power supply voltage. An increased voltage magnitude at the output stage is compensated by driving a channel field potential of the output device above the second power supply voltage.

### BACKGROUND

### 1. Field of Disclosure

The field of representative embodiments of this disclosure relates to voltage regulator circuits and amplifiers for implementing voltage regulators, and in particular to an amplifier having a split power supply providing leakage current management.

### 2. Background

In voltage regulator circuits, and other amplifier-based power output circuits, as output current requirements increase, the size/width of the output device or devices increases. In voltage regulator circuits, specifically, a single large pass device is used to provide the output. Increasing pass device size causes higher leakage current, which become significant at low load conditions, or when a voltage regulator is in a low-power operating mode such as a standby mode.

Therefore, it would be advantageous to provide an amplifier circuit and method of operation that provide reduced output leakage current, while supporting high output current levels.

### SUMMARY

Reduced output leakage current in an amplifier-based power output stage is accomplished in amplifier circuits, integrated circuits (ICs) including the amplifier circuits, and their methods of operation.

The amplifier circuit includes an amplifier stage that generates an output signal, an output stage including an output device and a pre-driver device coupled to a gate of the output device, and a feedback connection from the output device to provide the analog feedback signal to the one or more amplifier stages. A power supply rail of the amplifier is provided by a first power supply voltage, and the output signal of the amplifier stage is coupled to an input of the pre-driver device. A power supply rail of the output stage is provided by a second power supply voltage having a magnitude less than the first power supply voltage. The feedback connection compensates for an increased voltage magnitude at the output of the output stage by causing the amplifier stage to drive a channel field potential of the output device to a voltage having a magnitude greater than the second power supply voltage.

The summary above is provided for brief explanation and does not restrict the scope of the claims. The description below sets forth example embodiments according to this disclosure. Further embodiments and implementations will be apparent to those having ordinary skill in the art. Persons having ordinary skill in the art will recognize that various equivalent techniques may be applied in lieu of, or in conjunction with, the embodiments discussed below, and all such equivalents are encompassed by the present disclosure.

### BRIEF DESCRIPTION OF THE DRAWINGS

FIG. 1 is a block diagram illustrating an example system 10 in accordance with an embodiment of the disclosure.

FIG. 2 is a block diagram illustrating details of an example voltage regulator circuit 20, which may be used to implement LDO 16 in example system 10 of FIG. 1, in accordance with an embodiment of the disclosure.

FIG. 3 is a schematic diagram illustrating an example voltage regulator circuit 20A, which may be used to implement voltage regulator circuit 20 of FIG. 2, in accordance with an embodiment of the disclosure.

FIG. 4 is a schematic diagram illustrating another example voltage regulator circuit 20B, which may be used to implement voltage regulator circuit 20 of FIG. 2, in accordance with another embodiment of the disclosure.

FIG. 5 is a schematic diagram illustrating another example voltage regulator circuit 20C, which may be used to implement voltage regulator circuit 20 of FIG. 2, in accordance with another embodiment of the disclosure.

### DETAILED DESCRIPTION OF ILLUSTRATIVE EMBODIMENT

The present disclosure encompasses circuits and integrated circuits that include an amplifier stage that generates an output signal, an output stage including an output device and a pre-driver device coupled to a gate of the output device, and a feedback connection from the output device to provide the analog feedback signal to the one or more amplifier stages. A power supply rail of the amplifier may be provided by a first power supply voltage, and the output signal of the amplifier stage may be coupled to an input of the pre-driver device. A power supply rail of the output stage may be provided by a second power supply voltage having a magnitude less than the first power supply voltage. The feedback connection may compensate for an increased voltage magnitude at the output of the output stage by causing the amplifier stage to drive a channel field potential of the output device to a voltage having a magnitude greater than the second power supply voltage.

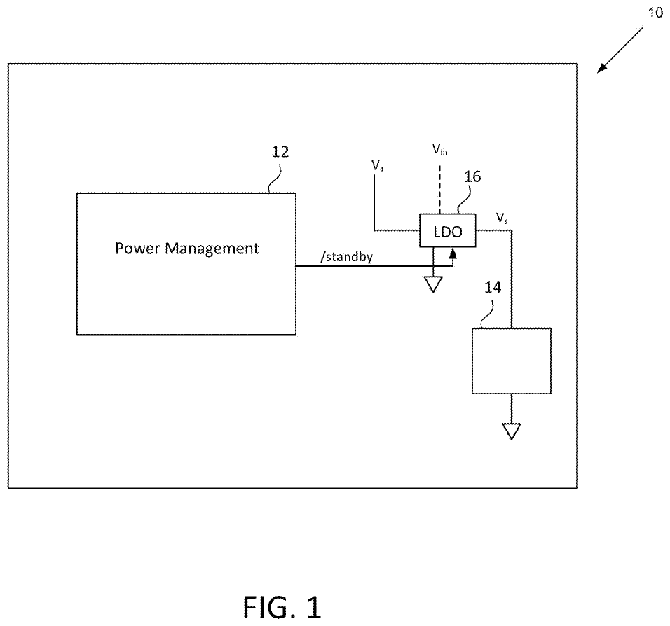

Referring now to FIG. 1, a block diagram illustrating an example system 10 is shown, in accordance with an embodiment of the disclosure. Example system 10 may form an integrated circuit (IC), form a portion of an IC, or may be implemented with separate ICs/devices. Example system 10 is only one example of a type of system in which voltage regulator circuits according to the various embodiments of the disclosure may be employed. A power management unit (PMU) 12 controls an operating state of functional units 14 within example system 10. A low-dropout voltage regulator (LDO) 16 provides operating power to functional units 14, and is responsive to a control signal /standby provided from PMU 12 to enter a standby state and remove operating power from functional units 14, for example, by shutting down the power output that supplies a supply voltage Vs to functional units 14.

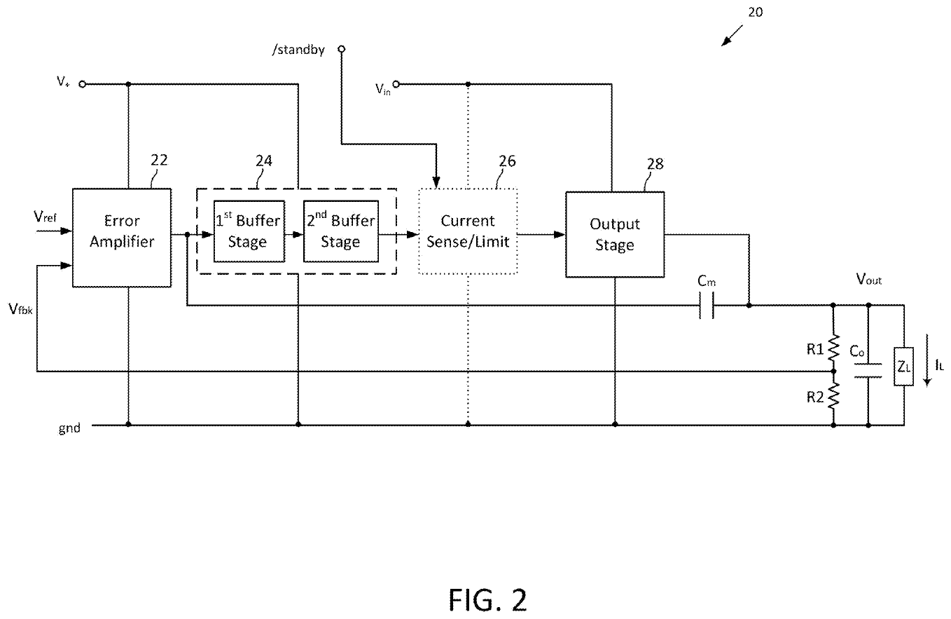

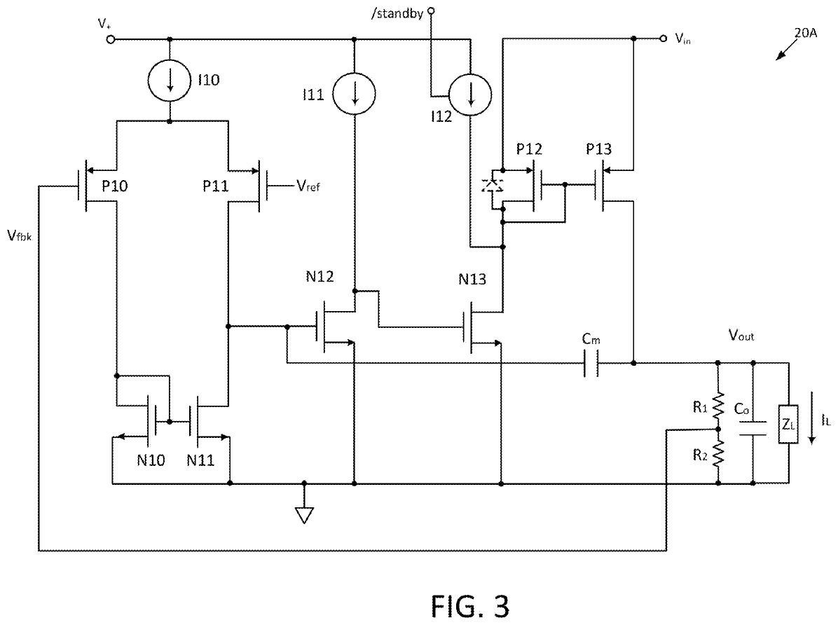

Referring now to FIG. 2, a block diagram illustrating details of an example voltage regulator circuit 20, which may be used to implement LDO 16 in example system 10 of FIG. 1, is shown, in accordance with an embodiment of the disclosure. Example voltage regulator circuit 20 is a linear regulator formed by a cascade of amplifier stages. A first stage implements an error amplifier 22 that generates an output by comparing a reference voltage V_{ref} with a feedback signal derived from an output voltage Vₒᵤₜ of example voltage regulator circuit 20 by a resistive divider composed of resistors R1 and R2. The output of error amplifier 22 is received by an intermediate amplifier stage 24 composed of two buffer amplifier stages. The output of intermediate amplifier stage 24 is optionally provided to a current level sense/limit block 26 that may determine an output current level provided by output stage 28, and which may prevent the input of output stage 28 being set to a level that exceeds a current limit value. In particular, with reference to the specific amplifier schemes described below with reference to FIGS. 3-5, the connection between intermediate amplifier stage 24 and output stage 28 may be accomplished by including a current mirror that multiplies a signal current level provided to the diode-connected input device of the current mirror by intermediate amplifier stage 24. Control signal /standby may be applied to disable example voltage regulator circuit 20 in various ways, e.g., to cause the signal path to turn off output stage 28, but in the depicted example, control signal /standby is applied to current level sense/limit block 26 to disable output stage 28. Output stage 28 is formed by an output device of the current mirror that is sized to produce an output current level that is greater than the input current provided through the diode-connected device by a factor of, e.g., 10×-100×, so that current sense/limit block 26 may be informed of an output current level by the current level provided through the diode-connected device of the current mirror. A capacitor Co represents a total capacitance at the output of example voltage regulator circuit 20, which may be a supplemental circuit capacitor, if required for stability. An impedance Z_{L} represents a load to which example voltage regulator circuit 20 delivers a load current I_{L}. A capacitor Cₘ is a degeneration/negative feedback capacitor provided to compensate example voltage regulator circuit 20 across nominal operating conditions.

A split power supply scheme that will be described in further detail below with reference to FIGS. 3-5, operates output stage 28 at a power supply voltage Vin that is significantly less than a power supply voltage V+ that operates error amplifier and intermediate amplifier stage 24, so that leakage through the larger power output device in output stage 28 can be reduced by driving the gate or the well of the power output device to a voltage above that of power supply voltage Vin, e.g., power supply voltage Vin may be a threshold voltage V_{T} less than power supply voltage V+ so that the cut-off threshold is just reached when load current I_{L} reaches zero, or the difference between power supply voltage V+ and power supply voltage Vin may be increased to further drive the output device into cut-off or for operating certain bias schemes that require a difference of at least 2V_{T} in some embodiments described in further detail below. A capacitor Co represents a total capacitance at the output of example voltage regulator circuit 20, which may be a supplemental circuit capacitor, if required for stability. An impedance Z_{L} represents a load to which example voltage regulator circuit 20 delivers a load current I_{L}. A capacitor Cₘ is a degeneration/negative feedback capacitor provided to compensate example voltage regulator circuit 20 across nominal operating conditions.

Referring now to FIG. 3, a schematic diagram illustrating an example voltage regulator circuit 20A, which may be used to implement voltage regulator circuit 20 of FIG. 2, is shown, in accordance with an embodiment of the disclosure. A pair of transistors P10, P11 provide a differential input stage to implement error amplifier 22 of FIG. 2, and a pair of transistors N10, N11 are connected to form a current mirror to bias the input stage, which splits a power supply current provided by current source I10 from power supply voltage V+. Transistors N12 and N13 implement the buffer amplifiers of intermediate amplifier stage 24 of FIG. 2, and are supplied with their respective operating currents by current sources I11 and I12. As mentioned above, control signal /standby may be applied to disable example voltage regulator circuit 20 in various ways, e.g., to cause the signal path to turn off transistor P13, but in the depicted example, control signal /standby is applied to disable current source I2, when control signal /standby is asserted. The output of the amplifier stages formed by transistors N12 and N13 is a current conducted by transistor N13, which is mirrored by a current mirror formed by transistors P12 and P13, in which transistor P12 provides the diode-connected input arm, and transistor P13 is the power output device that supplies output voltage Vₒᵤₜ and load current I_{L} to load Z_{L}. When load current I_{L} approaches zero, leakage current through transistor P13 may predominate over the actual target load current. Transistor P13 may be, for example, 10-100 times the size of transistor P12, in order to provide high efficiency by not wasting power supply current conducted through pre-driver/buffer device N13 and diode-connected mirror input device P12, which would otherwise be wasted in heat dissipated in voltage regulator circuit 20A, and which may further exacerbate leakage due to local thermal effects.

To reduce leakage through transistor P13, as mentioned above, transistors P12 and P13 are operated from lower (magnitude) power supply voltage Vᵢₙ, so that even during linear operation of example voltage regulator circuit 20A, the gate voltages of transistor P13 may exceed the voltage at the source terminal of transistor P13, driving transistor P13 into cut-off, reducing or eliminating leakage through transistor P13 to the output terminal of example voltage regulator circuit 20A. Thus, the gate voltage of transistor P13 is enabled to be bi-polar with respect to the source voltage which is power supply voltage Vᵢₙ. In order to accomplish the turn-off of transistor P13 in the depicted example, current source I12 is supplied from power supply voltage V+, which allows the drain terminal of transistor N13 to reach a voltage greater than power supply voltage Vᵢₙ, and which, in the depicted example, will be clamped by the body diode of transistor P12 at a voltage approximately a diode drop above power supply voltage Vᵢₙ+0.6V. Therefore, V_{gs} of transistor P13 will be approximately 0.6V, driving transistor P13 near cut-off and the leakage current near Ipso of transistor P13.

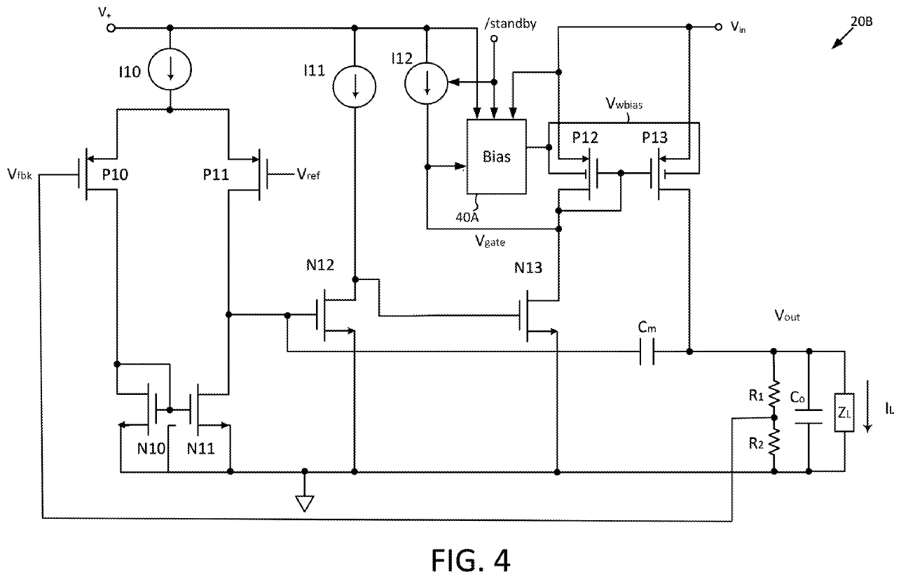

Referring now to FIG. 4, a schematic diagram illustrating another example voltage regulator circuit 20B, which may be used to implement voltage regulator circuit 20 of FIG. 2, is shown, in accordance with another embodiment of the disclosure. Example voltage regulator circuit 20B of FIG. 4 is similar to example voltage regulator circuit 20A of FIG. 3, so only differences between them will be described below. Rather than driving the gate voltages of transistors P12 and P13 to a voltage above power supply voltage Vᵢₙ, transistor P13 may be driven into cut-off by driving the wells of transistors P12 and P13 to a bias voltage V_{wbias} having a magnitude greater than power supply voltage Vᵢₙ. A bias circuit 40A applies a bias voltage V_{wbias} at least one threshold voltage greater than the gate voltage applied to transistors P12,P13 to the wells of transistors P12,P13 unless bias voltage V_{wbias} would be below power supply voltage Vᵢₙ, in which case bias circuit 40A will clamp bias voltage V_{wbias} at power supply voltage Vᵢₙ. Bias circuit may be, for example, an amplifier circuit that uses power supply voltage, Vᵢₙ, power supply voltage V+, and gate voltage V_{gate} to determine an optimum value for bias voltage V_{wbias}.

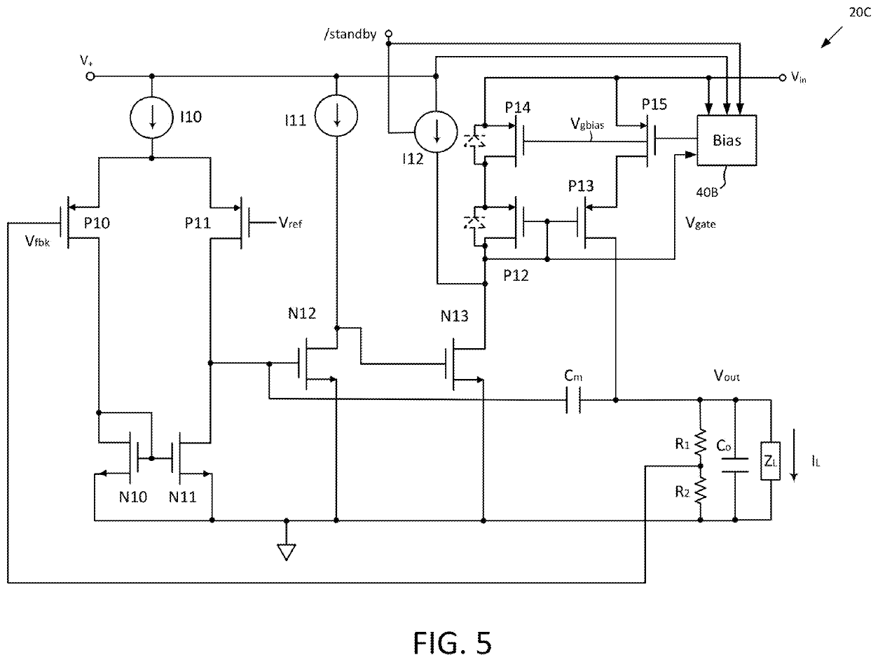

Referring now to FIG. 5, a schematic diagram illustrating another example voltage regulator circuit 20C, which may be used to implement voltage regulator circuit 20 of FIG. 2, in accordance with another embodiment of the disclosure. Example voltage regulator circuit 20C of FIG. 5 is similar to example voltage regulator circuit 20A of FIG. 3, so only differences between them will be described below. Voltage regulator circuit 20C includes one or more pairs of additional transistors P14, P15 connected between the respective drains of transistors P12 and P13 and power supply voltage Vᵢₙ, which allows the gate voltage V_{gate} of transistors P12 and P13 to be raised more than one threshold voltage V_{T} above the drains of transistors P12 and P13, depending on how many pairs of additional transistors P14, P15 are inserted in series between power supply voltage Vᵢₙ and the drains of transistors P12 and P13. (One pair per V_{T} increase in gate voltage V_{gate}.) A bias circuit 40B applies a bias voltage V_{gbias} at least one threshold voltage greater than the gate voltage applied to transistors P12,P13 to the gates of additional transistors P14,P15 unless bias voltage V_{gbias} would be below power supply voltage Vᵢₙ, in which case bias circuit 40B will clamp bias voltage V_{gbias} at power supply voltage Vᵢₙ. Bias circuit may be, for example, an amplifier circuit that uses power supply voltage, Vᵢₙ, power supply voltage V+, and gate voltage V_{gate} to determine an optimum value for bias voltage V_{gbias}.

In summary, this disclosure shows and describes circuits and integrated circuits implementing an amplifier that includes an amplifier stage that generates an output signal, an output stage including an output device and a pre-driver device coupled to a gate of the output device, and a feedback connection from the output device to provide the analog feedback signal to the one or more amplifier stages. A power supply rail of the amplifier may be provided by a first power supply voltage, and the output signal of the amplifier stage may be coupled to an input of the pre-driver device. A power supply rail of the output stage may be provided by a second power supply voltage having a magnitude less than the first power supply voltage. The feedback connection may compensate for an increased voltage magnitude at the output of the output stage by causing the amplifier stage to drive a channel field potential of the output device to a voltage having a magnitude greater than the second power supply voltage.

In some example embodiments, the output device and the pre-driver device may form a current mirror that multiplies a first current through a diode-connected pre-driver device to determine a second current conducted through the output device. In some example embodiments, a gate of the output device may be driven to the voltage having a magnitude greater than the second power supply voltage by driving the output signal of the amplifier stage to a first voltage one threshold voltage greater in magnitude than the second power supply voltage. In some example embodiments, the gate of the output device may be driven to the voltage having a magnitude greater than the second power supply voltage by driving the output signal of the amplifier stage to a second voltage greater in magnitude than the first voltage, and wherein the gate of the output device is held at the first voltage by conduction of a body diode of the pre-driver device from a drain of the pre-driver device to the second power supply voltage. In some example embodiments, a swing of the voltage at the gate of the output device may be bipolar with respect to a voltage at the source of the output device during operation. In some example embodiments, the amplifier may form a low-dropout regulator (LDO) regulated power supply circuit, and the output device may provide the output of the LDO. In some example embodiments, in a standby mode of operation, the output of the LDO may be prevented from turning on by the driving of the gate of the output device to the voltage greater than the second power supply voltage.

In some example embodiments, the amplifier stage may be coupled to a well of the output device and may drive the channel field potential of the output device to a potential magnitude greater than the second power supply by the pre-driver raising a magnitude of a voltage provided to the gate of the output device to a potential magnitude greater than that of the second power supply voltage. In some example embodiments, the amplifier stage may be coupled to a well of the pre-driver device and may drive the channel field potential of the output device to a potential magnitude greater than the second power supply by raising a magnitude of a voltage provided to the well of the output device to a potential magnitude greater than that of the second power supply voltage. In some example embodiments, the amplifier stage may receive an analog feedback signal from the output device, so that driving of the channel field potential of the output device to the voltage above the second power supply may compensate for leakage that would otherwise be caused by the output device. In some example embodiments, the amplifier may form a regulated power supply circuit, and the output device may provide the output of the regulated power supply circuit.

While the disclosure has shown and described particular embodiments of the techniques disclosed herein, it will be understood by those skilled in the art that the foregoing and other changes in form, and details may be made therein without departing from the spirit and scope of the disclosure. For example, the techniques shown above may be applied to another circuit or system having an amplifier with a power output stage, such as a motor controller or audio amplifier.

What is claimed is:

1. An amplifier, comprising:
an amplifier stage that generates an output signal, and wherein a power supply rail of the amplifier is provided by a first power supply voltage;
an output stage including an output device and a pre-driver device coupled to a gate of the output device, wherein the output signal of the amplifier stage is coupled to an input of the pre-driver device, wherein a power supply rail of the output stage is provided by a second power supply voltage having a magnitude less than the first power supply voltage; and
a feedback connection from the output device to provide an analog feedback signal to the one or more amplifier stages, wherein the feedback connection compensates for an increased voltage magnitude at the output of the output stage by causing the amplifier stage to drive a channel field potential of the output device to a voltage having a magnitude greater than the second power supply voltage.

2. The amplifier of claim 1, wherein the output device and the pre-driver device form a current mirror that multiplies a first current through a diode-connected pre-driver device to determine a second current conducted through the output device.

3. The amplifier of claim 2, wherein a gate of the output device is driven to the voltage having a magnitude greater than the second power supply voltage by driving the output signal of the amplifier stage to a first voltage one threshold voltage greater in magnitude than the second power supply voltage.

4. The amplifier of claim 3, wherein the gate of the output device is driven to the voltage having a magnitude greater than the second power supply voltage by driving the output signal of the amplifier stage to a second voltage greater in magnitude than the first voltage, and wherein the gate of the output device is held at the first voltage by conduction of a body diode of the pre-driver device from a drain of the pre-driver device to the second power supply voltage.

5. The amplifier of claim 3, wherein a swing of the voltage at the gate of the output device is bipolar with respect to a voltage at the source of the output device during operation.

6. The amplifier of claim 5, wherein the amplifier forms a low-dropout regulator (LDO) regulated power supply circuit, wherein the output device provides the output of the LDO, and wherein, in a standby mode of operation, the output of the LDO is prevented from turning on by the driving of the gate of the output device to the voltage greater than the second power supply voltage.

7. The amplifier of claim 1, wherein the amplifier stage is coupled to a well of the output device and drives the channel field potential of the output device to a potential magnitude greater than the second power supply by the pre-driver raising a magnitude of a voltage provided to the gate of the output device to a potential magnitude greater than that of the second power supply voltage.

8. The amplifier of claim 1, wherein the amplifier stage is coupled to a well of the pre-driver device and drives the channel field potential of the output device to a potential magnitude greater than the second power supply by raising a magnitude of a voltage provided to the well of the output device to a potential magnitude greater than that of the second power supply voltage.

9. The amplifier of claim 1, wherein the amplifier stage receives an analog feedback signal from the output device, wherein driving of the channel field potential of the output device to the voltage above the second power supply compensates for leakage that would otherwise be caused by the output device.

10. The amplifier of claim 1, wherein the amplifier forms a regulated power supply circuit, wherein the output device provides the output of the regulated power supply circuit.

11. A method of reducing leakage in an output stage of a feedback amplifier circuit under no-load or low-load conditions, the method comprising:
providing a first power supply voltage having a magnitude greater than a second power supply voltage of the output stage to one or more amplifier stages connected in cascade that provide an input to the output stage; and
coupling a pre-driver of the output stage to the first power supply with a bias source, and providing an output of the pre-driver to an output device of the output stage, so that a channel field potential of the output device is driven to a voltage having a magnitude greater than the second power supply voltage.

12. The method of claim 11, wherein the output device forms a current mirror with a diode-connected pre-driver device of the pre-driver, wherein the method comprises operating the current mirror by multiplying a first current conducted through the diode-connected pre-driver device to determine a second current conducted through the output device.

13. The method of claim 12, wherein the method comprises driving a gate of the output device to the voltage having a magnitude greater than the second power supply voltage by driving the output signal of the amplifier stage to a first voltage one threshold voltage greater in magnitude than the second power supply voltage.

14. The method of claim 13, further comprising driving the gate of the output device to the voltage having a magnitude greater than the second power supply voltage by driving the output signal of the amplifier stage to a second voltage greater in magnitude than the first voltage, and wherein the gate of the output device is held at the first voltage by conduction of a body diode of the pre-driver device from a drain of the pre-driver device to the second power supply voltage.

15. The method of claim 13, wherein a swing of the voltage at the gate of the output device is bipolar with respect to a voltage at the source of the output device during operation.

16. The method of claim 15, wherein the amplifier forms a low-dropout regulator (LDO) regulated power supply circuit, wherein the method further comprises:
providing the output of the LDO from the output device; and
responsive to commencing a standby mode of operation, preventing the output of the LDO from turning on by the driving of the gate of the output device to the voltage greater than the second power supply voltage.

17. The method of claim 11, further comprising:
coupling an output of the one or more amplifier stages to a well of the output device, and
driving a channel field potential of the output device to a potential magnitude greater than the second power supply by the pre-driver raising a magnitude of a voltage provided to the gate of the output device to a potential magnitude greater than that of the second power supply voltage.

18. The method of claim 11, further comprising:
coupling an output of the one or more amplifier stages to a well of the output device; and
driving the channel field potential of the output device to a potential magnitude greater than the second power supply by the pre-driver raising a magnitude of a voltage provided to the well of the output device to a potential magnitude greater than that of the second power supply voltage.

19. The method of claim 11, further comprising receiving an analog feedback signal from the output device at an input of the one or more amplifier stages, wherein the driving of the channel field potential of the output device to the voltage above the second power supply compensates for leakage that would otherwise be caused by the output device.

20. The method of claim 11, wherein the amplifier forms a regulated power supply circuit, and wherein the method further comprises providing the output of the regulated power supply circuit from the output device.
